(19) United States
(12) Patent Application Publication
(10) Pub. No.: US 2018/0263139 A1
(43) Pub. Date: Sep. 13, 2018

(54) HEAT-DISSIPATION ASSEMBLY AND PROJECTOR

(71) Applicant: DELTA ELECTRONICS, INC., Taoyuan City (TW)

(72) Inventors: Meng-Sheng CHANG, Taoyuan City (TW); Hui-Hsiung WANG, Taoyuan City (TW)

(21) Appl. No.: 15/609,006

(22) Filed: May 30, 2017

(30) Foreign Application Priority Data
Mar. 13, 2017 (CN) 201710144760.3

(51) Int. Cl. H05K 7/20; G05D 23/19

(52) U.S. Cl. CPC H05K 7/20409; G05D 23/1928; G05D 23/19

(57) ABSTRACT

A heat-dissipation assembly is used to dissipate heat of a heat source. The heat-dissipation assembly includes a thermally conductive structure, a thermoelectric cooler, and a temperature sensor. The thermally conductive structure includes a main body and a protruding portion. The main body has a first surface and a second surface respectively located at opposite sides of the main body. The protruding portion is connected to the first surface and configured to be thermally connected to the heat source. The thermoelectric cooler is thermally connected to the second surface. The temperature sensor is thermally connected to the first surface. An orthographic projection of the thermoelectric cooler on the first surface covers at least a part of the temperature sensor.

### RELATED APPLICATIONS

This application claims priority to China Application Serial Number 201710144760.3, filed Mar. 13, 2017, which is herein incorporated by reference.

### BACKGROUND

### Technical Field

The present disclosure relates to a heat-dissipation assembly, and more particularly, to a projector using the heat-dissipation assembly.

### Description of Related Art

Projectors have been applied to various fields (from consumer products to high-tech products) with the development of science and technology, and their applications have been extending. For example, the applications include enlarging an object by a projection system in a large-scale conference or instantly showing images by a commercial projection screen or a TV in presentation.

As the brightness of the projectors continues to rise, traditional ways of dissipating heat have often been unable to meet the demand. When the brightness is more than ten thousand lumens, it is difficult to dissipate the heat generated by the core components, such as digital micromirror devices (DMDs).

Presently, there exists a conventional projector using a thermoelectric cooler cooperating with a temperature sensor to control the temperature of the digital micromirror devices. To achieve the purpose of dissipating the heat of the digital micromirror devices, the temperature sensor is used to reflect the temperature of the cold surface of the thermoelectric cooler, and the cooling power of the thermoelectric cooler is controlled by software. However, if the temperature sensor cannot precisely reflect the temperature of the cold surface of the thermoelectric cooler, the cooling power of the thermoelectric cooler might be too large or too small. When the cooling power of the thermoelectric cooler might be too large, the temperature of the cold surface will lower than the ambient temperature, which results in condensation of water on the cold surface and thus produces the risk of electrical short circuit. When the cooling power of the thermoelectric cooler might be too small, the purpose of dissipating heat cannot be achieved.

### SUMMARY

An aspect of the disclosure is to provide a heat-dissipation assembly and a projector using the heat-dissipation assembly that can precisely reflect the temperature.

According to an embodiment of the disclosure, a heat-dissipation assembly is used to dissipate heat of a heat source. The heat-dissipation assembly includes a thermally conductive structure, a thermoelectric cooler, and a temperature sensor. The thermally conductive structure includes a main body and a protruding portion. The main body has a first surface and a second surface respectively located at opposite sides of the main body. The protruding portion is connected to the first surface and configured to be thermally connected to the heat source. The thermoelectric cooler is thermally connected to the second surface. The temperature sensor is thermally connected to the first surface. An orthographic projection of the thermoelectric cooler on the first surface covers at least a part of the temperature sensor.

According to another embodiment of the disclosure, a projector includes a digital micromirror device, a fixing structure, a thermally conductive structure, a thermoelectric cooler, and a temperature sensor. The fixing structure is connected to the digital micromirror device. The thermally conductive structure includes a main body and a protruding portion. The main body has a first surface and a second surface respectively located at opposite sides of the main body. The protruding portion is connected to the first surface and passes through the fixing structure to be thermally connected to the digital micromirror device. The thermoelectric cooler is thermally connected to the second surface. The temperature sensor is thermally connected to the first surface. An orthographic projection of the thermoelectric cooler on the first surface covers at least a part of the temperature sensor.

In an embodiment of the disclosure, the orthographic projection entirely covers the temperature sensor.

In an embodiment of the disclosure, the main body has a recess formed on the first surface. The temperature sensor is at least partially located in the recess.

In an embodiment of the disclosure, a gap exists between the first surface and the fixing structure. The recess has a depth relative to the first surface. The gap is smaller than the depth.

In an embodiment of the disclosure, the gap is smaller than 3 mm.

In an embodiment of the disclosure, the heat-dissipation assembly further includes a heat sink. The heat sink is thermally connected to a surface of the thermoelectric cooler away from the thermally conductive structure.

Accordingly, in the heat-dissipation assembly and the projector using the heat-dissipation assembly of the disclosure, the thermoelectric cooler and the temperature sensor are respectively disposed at opposite sides of the main body of the thermally conductive structure, and the temperature sensor is located within the projection range of the thermoelectric cooler, so the spreading resistance between the thermoelectric cooler and the temperature sensor can be reduced, such that the temperature sensor can precisely reflect the temperature of the cold surface of the thermoelectric cooler. Furthermore, in the heat-dissipation assembly and the projector of the disclosure, a recess can be further formed on the main body of the thermally conductive structure, so as to reduce the distance from the main body of the thermally conductive structure to the heat source (i.e., to reduce the length of the protruding portion of the thermally conductive structure), thereby greatly reducing the thermal resistance between the thermoelectric cooler and the heat source.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a side view of some components of a projector according to an embodiment of the disclosure;

FIG. 2 is a front view of the thermally conductive structure and the temperature sensor in FIG. 1;

FIG. 3 is a side view of some components of a projector according to another embodiment of the disclosure;

FIG. 4 is a curve diagram showing temperature-voltage curves respectively detected at different locations by controlling the voltage of the thermoelectric cooler; and

FIG. 5 is a side view of some components of a projector according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

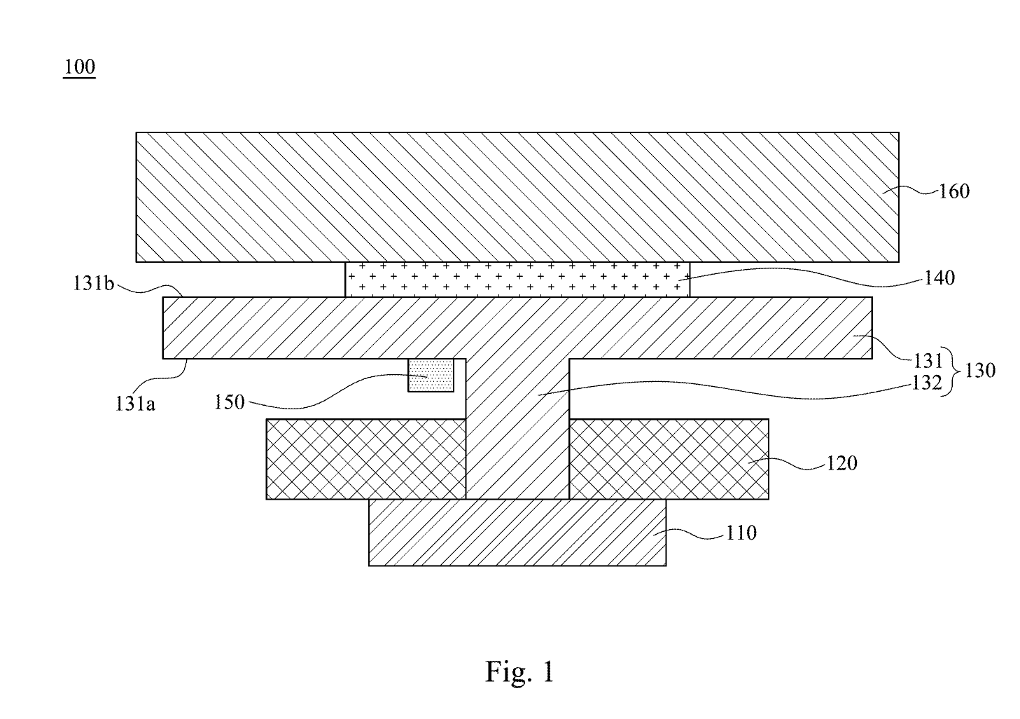

Reference is made to FIG. 1. FIG. 1 is a side view of some components of a projector 100 according to an embodiment of the disclosure. As shown in FIG. 1, in the embodiment, the projector 100 includes a digital micromirror device 110, a fixing structure 120, a thermally conductive structure 130, a thermoelectric cooler 140, a temperature sensor 150, and a heat sink 160. The fixing structure 120 is connected to the digital micromirror device 110, so as to fix the digital micromirror device 110 at a predetermined location in the projector 100. The thermally conductive structure 130 includes a main body 131 and a protruding portion 132. The main body 131 has a first surface 131a and a second surface 131b respectively located at opposite sides of the main body 131. The protruding portion 132 is connected to the first surface 131a and passes through the fixing structure 120 to be thermally connected to the digital micromirror device 110. The thermoelectric cooler 140 is thermally connected to the second surface 131b. The temperature sensor 150 is thermally connected to the first surface 131a. The temperature sensor 150 is aligned with the thermoelectric cooler 140 through a part of the main body 131. The heat sink 160 is thermally connected to a surface of the thermoelectric cooler 140 away from the thermally conductive structure 130.

Specifically, a cold surface of the thermoelectric cooler 140 is connected to the second surface 131b, and a hot surface of the thermoelectric cooler 140 is connected to the heat sink 160. By applying a voltage to the thermoelectric cooler 140, a temperature difference will produced between the cold surface and the hot surface of the thermoelectric cooler 140, so that the cold surface can be used to cool the main body 131 of the thermally conductive structure 130, and the hot surface can be used to heat the heat sink 160. From another point of view, it can be seen that the thermoelectric cooler 140 absorbs the heat of the main body 131 of the thermally conductive structure 130 through the cold surface and then transfers the absorbed heat to the heat sink 160 through the hot surface. Finally, the heat sink 160 dissipates the heat transferred from the hot surface to the air.

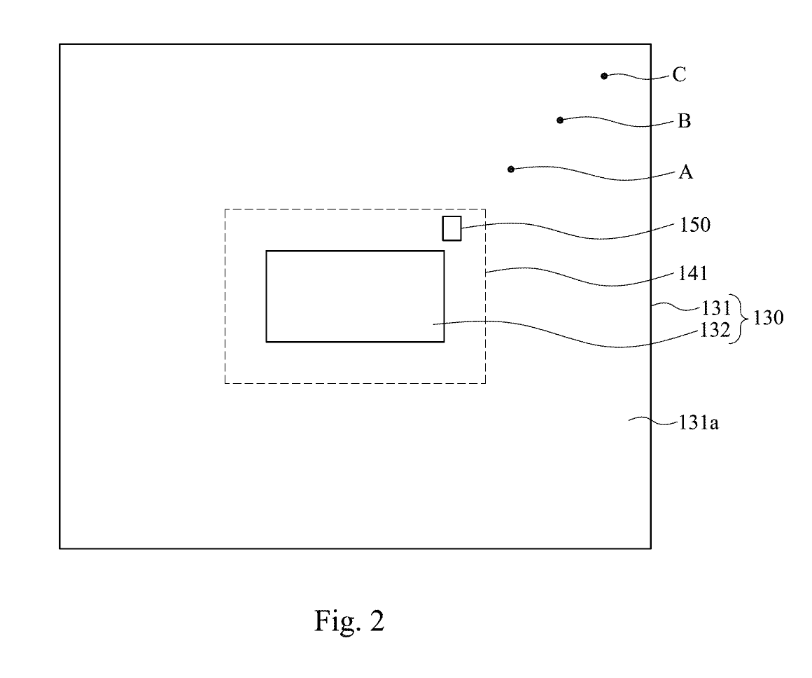

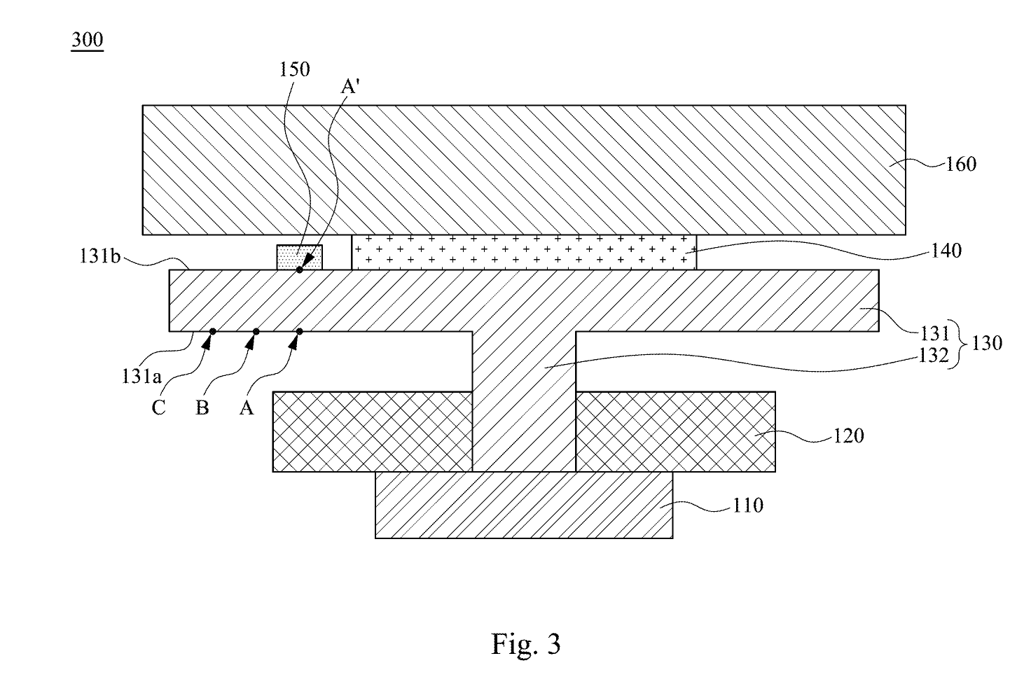

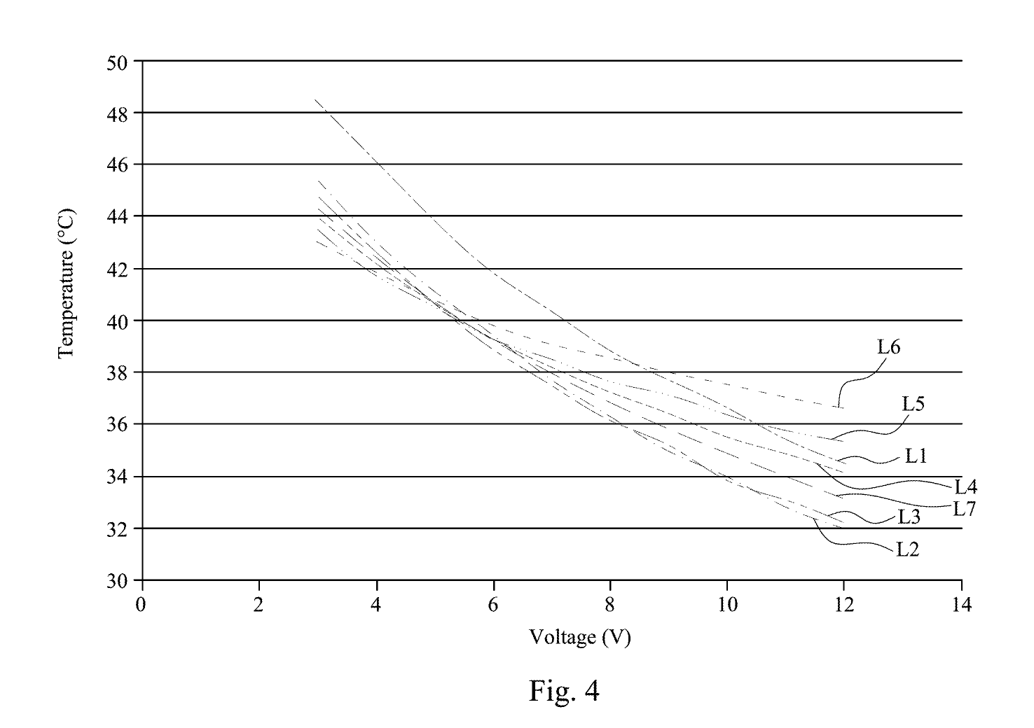

Reference is made to FIG. 2. FIG. 2 is a front view of the thermally conductive structure 130 and the temperature sensor 150 in FIG. 1. As shown in FIG. 2, in the embodiment, an orthographic projection 141 (indicated by a dotted line) of the thermoelectric cooler 140 on the first surface 131a entirely covers the temperature sensor 150. Reference is further made to FIGS. 3 and 4. FIG. 3 is a side view of some components of a projector 300 according to another embodiment of the disclosure. FIG. 4 is a curve diagram showing temperature-voltage curves respectively detected at different locations by controlling the voltage of the thermoelectric cooler 140. Specifically, FIG. 4 shows the temperature-voltage curves respectively detected on temperature sensor 150 which is located within the orthographic projection 141, at location A, at location B, at location C shown in FIG. 2, and at location A′ which is at the second surface 131b shown in FIG. 3; detected on the cold surface of the thermoelectric cooler 140; and detected on the digital micromirror device 110, by controlling the voltage of the thermoelectric cooler 140. The locations A, A′, B, and C are not within the range of the orthographic projection 141, and the distances from the orthographic projection 141 respectively to the locations A, A′, B, and C are gradually increasing.

It can be clearly seen from FIG. 4 that three temperature-voltage curves L1, L2, and L3 respectively detected on the digital micromirror device 110, the cold surface of the thermoelectric cooler 140, and the temperature sensor 150 which is located within the orthographic projection 141 obviously have a high degree of linear relationship. In detail, the temperature-voltage curves L2 and L3 respectively detected on the cold surface of the thermoelectric cooler 140 and the temperature sensor 150 which is located within the orthographic projection 141 almost nearly coincide. A temperature difference between L1 and L2 based on the same voltage, or a temperature difference between L1 and L3 based on the same voltage, remains substantially a constant value with various applied voltage. On the contrary, the temperature-voltage curves L4, L5, L6, and L7 respectively detected at the locations A, B, C, and A′ are obviously nonlinear to the temperature-voltage curves L1 and L2 respectively detected at the digital micromirror device 110 and the cold surface of the thermoelectric cooler 140, and the temperature-voltage curve L6 detected at the location C furthest from the orthographic projection 141 has the largest deviation. Even the location A′ and the thermoelectric cooler 140 are both located on the second surface 131b and close to each other, the detected temperature-voltage curve L7 is still nonlinear to the temperature-voltage curves L1 and L2. This is because the locations A, A′, B, and C are located out of the range of the orthographic projection 141, so additional spreading resistances will produced due to the heat transfer paths of different shapes. Moreover, if the temperature sensor 150 is disposed at the location C which is close to the outside, the temperature sensor 150 will greatly influenced by the ambient temperature, which results in the foregoing largest deviation.

It can be seen that if the temperature sensor 150 is disposed within the range of the orthographic projection 141 of the thermoelectric cooler 140 in the embodiment, the temperature detected by the temperature sensor 150 can precisely reflect the temperature of the cold surface of the thermoelectric cooler 140 (or the digital micromirror device 110). Hence, a user can easily know (or easily estimate) whether the digital micromirror device 110 is controlled to a predetermined temperature simply according to the temperature detected by the temperature sensor 150.

In some embodiments, the orthographic projection 141 of the thermoelectric cooler 140 on the first surface 131a can only cover at least a part of the temperature sensor 150.

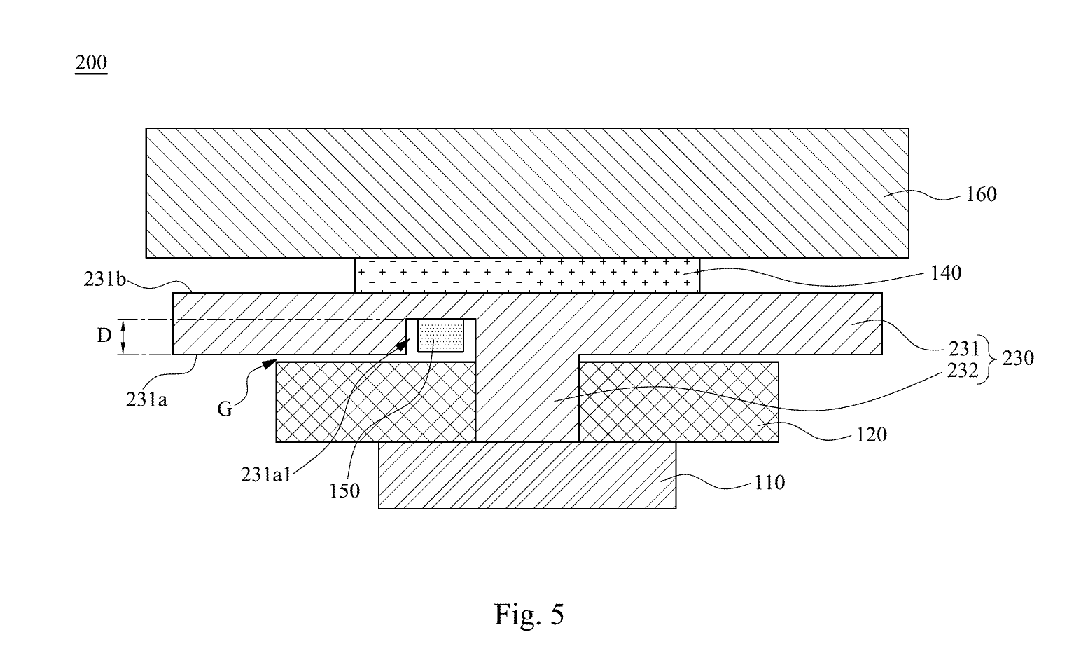

Reference is made to FIG. 5. FIG. 5 is a side view of some components of a projector 200 according to another embodiment of the disclosure. As shown in FIG. 5, in the embodiment, the projector 200 includes a digital micromirror device 110, a fixing structure 120, a thermally conductive structure 230, a thermoelectric cooler 140, a temperature sensor 150, and a heat sink 160. The digital micromirror device 110, the fixing structure 120, the thermoelectric cooler 140, the temperature sensor 150, and the heat sink 160 of the present embodiment are similar to those of the embodiment in FIG. 1, so reference can be made to the foregoing descriptions and therefore are not repeated here to avoid duplicity.

The difference between the present embodiment and the embodiment in FIG. 1 is that the thermally conductive structure 230 in the present embodiment is modified. Specifically, in the embodiment, the thermally conductive structure 230 includes a main body 231 and a protruding portion 232 connected to each other. The main body 231 has a first surface 231a and a second surface 231b respectively located at opposite sides of the main body 231. The main body 231 has a recess 231a1 formed on the first surface 231a. The temperature sensor 150 is at least partially located in the recess 231a1. Therefore, compared with the thermally conductive structure 130, the length of the protruding portion 232 of the present embodiment can be reduced, so as to reduce the distance from the main body 231 of the thermally conductive structure 230 to the digital micromirror device 110, thereby greatly reducing the thermal resistance between the thermoelectric cooler 140 and the digital micromirror device 110. Under the circumstance, the thermoelectric cooler 140 adopted in the projector 200 of the present embodiment can have a smaller maximum cooling power, thereby saving the component cost.

In the embodiment, a gap G exists between the first surface 231a and the fixing structure 120. The recess 231a1 has a depth D relative to the first surface 231a, and the gap G is smaller than the depth D. Hence, the temperature sensor 150 can be entirely accommodated in the recess 231a1 of the main body 231 in the projector 200 of the present embodiment. Alternatively, in other embodiments, the temperature sensor 150 can be mostly accommodated in the recess 231a1 of the main body 231. Therefore, the internal space usage of the projector 200 of the present embodiment can be improved.

In some embodiment, the gap G between the first surface 231a and the fixing structure 120 is smaller than 3 mm, but the disclosure is not limited in this regard.

According to the foregoing recitations of the embodiments of the disclosure, it can be seen that in the heat-dissipation assembly and the projector using the heat-dissipation assembly of the disclosure, the thermoelectric cooler and the temperature sensor are respectively disposed at opposite sides of the main body of the thermally conductive structure, and the temperature sensor is located within the projection range of the thermoelectric cooler, so the spreading resistance between the thermoelectric cooler and the temperature sensor can be reduced, such that the temperature sensor can precisely reflect the temperature of the cold surface of the thermoelectric cooler. Furthermore, in the heat-dissipation assembly and the projector of the disclosure, a recess can be further formed on the main body of the thermally conductive structure, so as to reduce the distance from the main body of the thermally conductive structure to the heat source (i.e., to reduce the length of the protruding portion of the thermally conductive structure), thereby greatly reducing the thermal resistance between the thermoelectric cooler and the heat source.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A heat-dissipation assembly for dissipating heat of a heat source, the heat-dissipation assembly comprising:
a thermally conductive structure comprising:
a main body having a first surface and a second surface respectively located at opposite sides of the main body; and
a protruding portion connected to the first surface and configured to be thermally connected to the heat source;
a thermoelectric cooler thermally connected to the second surface; and
a temperature sensor thermally connected to the first surface,
wherein an orthographic projection of the thermoelectric cooler on the first surface covers at least a part of the temperature sensor.

2. The heat-dissipation assembly of claim 1, wherein the orthographic projection entirely covers the temperature sensor.

3. The heat-dissipation assembly of claim 1, wherein the main body has a recess formed on the first surface, and the temperature sensor is at least partially located in the recess.

4. The heat-dissipation assembly of claim 1, further comprising a heat sink thermally connected to a surface of the thermoelectric cooler away from the thermally conductive structure.

5. A projector, comprising:
a digital micromirror device;
a fixing structure connected to the digital micromirror device;
a thermally conductive structure comprising:
a main body having a first surface and a second surface respectively located at opposite sides of the main body; and
a protruding portion connected to the first surface and passing through the fixing structure to be thermally connected to the digital micromirror device;
a thermoelectric cooler thermally connected to the second surface; and
a temperature sensor thermally connected to the first surface,
wherein an orthographic projection of the thermoelectric cooler on the first surface covers at least a part of the temperature sensor.

6. The projector of claim 5, wherein the orthographic projection entirely covers the temperature sensor.

7. The projector of claim 5, wherein the main body has a recess formed on the first surface, and the temperature sensor is at least partially located in the recess.

8. The projector of claim 7, wherein a gap exists between the first surface and the fixing structure, the recess has a depth relative to the first surface, and the gap is smaller than the depth.

9. The projector of claim 8, wherein the gap is smaller than 3 mm.

10. The projector of claim 5, further comprising a heat sink thermally connected to a surface of the thermoelectric cooler away from the thermally conductive structure.
